(19) United States
(12) Patent Application Publication
(10) Pub. No.: US 2008/0311527 A1
(43) Pub. Date: Dec. 18, 2008

(54) Method of forming protection layer on photoresist pattern and method of forming fine pattern using the same

(75) Inventors: Do-Young KIM, Hwaseong-si (KR); Hong LEE, Suwon-si (KR); Young-Ho KIM, Yongin-si (KR); Boo-Deuk KIM, Suwon-si (KR); Hyo-Jin YUN, Anyang-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/155,507

(22) Filed: Jun. 5, 2008

(30) Foreign Application Priority Data
Jun. 18, 2007 (KR) 10-2007-0059548

(51) Int. Cl. G03F 7/20

(52) U.S. Cl. 430/313; 430/325; 430/323

(57) ABSTRACT

A method of forming a protection layer on a photoresist pattern and a method of forming a fine pattern using the same are provided. A photoresist layer may be formed on a substrate. Exposure regions and non-exposure regions may be defined in the photoresist layer by an exposure process. A reactive material layer may be formed on the photoresist layer having the exposure regions. A protection layer may be formed on the exposure regions by the reactive material layer reacting via a chemical attachment process. The non-exposure regions and the reactive material layer that remains after the reaction may be removed by a development process to form photoresist patterns. The substrate may be etched using the protection layer and the photoresist patterns as etching masks.

### PRIORITY STATEMENT

This application claims priority under U.S.C. §119 to Korean Patent Application No. 10-2007-0059548, filed Jun. 18, 2007, in the Korean Intellectual Property Office (KIPO), the entire contents of which are incorporated herein by reference.

### BACKGROUND

1. Field

Example embodiments relate to a method of forming a fine pattern, and more particularly, to a method of forming a protection layer on a photoresist pattern and a method of forming a fine pattern using the same.

2. Description of the Related Art

A plurality of patterning processes may be employed in manufacturing electronic parts, e.g., a semiconductor device and a liquid crystal display (LCD). Research aiming at extremely reducing the fine patterns to meet demand for light, thin, short and small electronic parts may be underway. A technique including forming a photoresist pattern on a substrate, and forming a variety of fine patterns on the substrate using the photoresist pattern as an etch mask may be widely employed in the patterning processes. The fine patterns may be formed by an etching process. During the etching process, the photoresist pattern may be etched at a predetermined or given ratio. Accordingly, while the etching processes may be performed, the photoresist pattern may have sufficient thickness and etching resistance to protect the fine pattern.

The minimum size of the photoresist pattern may be determined by the resolution limit of an exposure apparatus. The resolution limit of the exposure apparatus may be determined depending on the wavelength of a light source to be used. That is, the shorter the wavelength of the light source is, the greater the resolution limit of the exposure apparatus may become. The shorter the wavelength of the light source, the less the depth of focus (DOF) of the exposure apparatus becomes as well.

A photoresist layer thicker than the DOF may cause an exposure error, e.g., defocus. For example, a photoresist layer thicker than the DOF may deteriorate the resolution limit of the exposure apparatus. Therefore, the thickness of the photoresist layer may be reduced to a thickness corresponding to the DOF. Accordingly, obtaining a sufficient thickness to form the fine patterns only with the photoresist patterns may be difficult. Methods of forming coating layers on surfaces of the photoresist patterns may be researched to ensure etching resistance of the mask pattern.

For example, another conventional method of forming a fine pattern may include forming a first photoresist pattern on a substrate. The first photoresist pattern may be filled with a second photoresist therein. The second photoresist may be formed of a material layer that does not cross-link the first photoresist pattern. A third photoresist may be applied on the first photoresist pattern. A cross-linking layer of the third photoresist may be formed on the first photoresist pattern. The second photoresist and the third photoresist that remains after the reaction may be removed, so that a third photoresist pattern may be formed on the first photoresist pattern.

However, controlling the process of filling the second photoresist in the first photoresist pattern may be difficult. For example, the second photoresist may remain on the upper surface of the first photoresist pattern. Also, the second photoresist may be excessively recessed, so that sidewalls of the first photoresist pattern may be partially exposed. In addition, while the second photoresist may be formed, the thickness of the first photoresist pattern may be reduced.

When the second photoresist remains on the upper surface of the first photoresist pattern, the cross-linking layer of the third photoresist may be abnormally formed. When the sidewalls of the first photoresist pattern are exposed, a cross-linking layer of the second photoresist may partially cover the sidewalls of the first photoresist pattern. Therefore, controlling the size of the fine patterns may be difficult.

### SUMMARY

Example embodiments provide a method of forming a protection layer on a photoresist pattern. Other example embodiments provide a method of forming a fine pattern using a protection layer on a photoresist pattern.

Example embodiments are directed to a method of forming a protection layer on a photoresist pattern. A photoresist layer may be formed on a substrate. Exposure regions and non-exposure regions may be defined in the photoresist layer by an exposure process. A reactive material layer may be formed on the photoresist layer having the exposure regions. A protection layer may be formed on the exposure regions via reacting the reactive material layer by a chemical attachment process. Photoresist patterns may be formed by a development process allowing for the removal of the non-exposure regions and the reactive material layer that remains after the reaction. The protection layer may be formed to remain on the photoresist patterns.

Example embodiments are also directed to a method of forming a fine pattern. The method may include providing a substrate and forming the protection layer according to the method of example embodiments. The substrate may be etched using the protection layer and the photoresist patterns as etching masks.

In example embodiments, the photoresist layer may be made of a negative photoresist. In example embodiments, before forming the photoresist layer, an anti-reflective layer may be formed on the substrate. In example embodiments, the reactive material layer may be formed to cover the exposure regions and the non-exposure regions.

In example embodiments, first exposure regions may be formed on the photoresist layer by a first exposure process. Second exposure regions may be formed between the first exposure regions by a second exposure process. As a result, the non-exposure regions may be defined between the exposure regions.

In example embodiments, the chemical attachment process may include heating the photoresist layer and the reactive material layer to diffuse hydrogen ions (H+) generated from the exposure regions into the reactive material layer. Heating the photoresist layer and the reactive material layer may be performed at a temperature of about 90° C. to about 150° C. In example embodiments, the protection layer may cover the non-exposure regions. The reactive material layer that does not react may remain on the non-exposure regions.

In example embodiments, sidewalls of the photoresist patterns may be exposed. In example embodiments, the reactive material layer may be formed of at least one selected from the group consisting of an acrylate group represented by Formula 1, a poly hydroxy styren (PHS) group represented by Formula 2, and a poly vinyl alcohol (PVA) group represented by Formula 3.

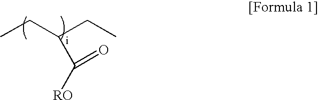

wherein R represents one selected from an electron donating group consisting of an alkyl group and H, and i represents an integer of 1 to 5000;

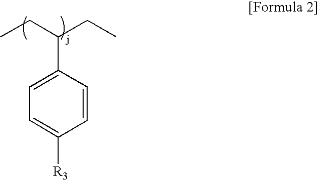

wherein R3 represents one selected from an electron donating group consisting of an alkyl group and H or one selected from a blocking group consisting of tertiary-butyloxycarbonyl (t-Boc) and acetal, and j represents an integer of 1 to 5000; and

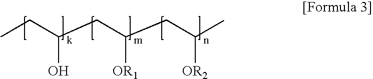

wherein R1 and R2 respectively represent one selected from the group consisting of acetyl, acetal, an alkyl group and H, and k, m and n, respectively, represent an integer of 1 to 100.

In example embodiments, the substrate may be a semiconductor substrate. A thin film selected from the group consisting of a conductive layer, a dielectric layer, and a combination thereof may be formed on the semiconductor substrate. In example embodiments, the photoresist layer may be made of a negative photoresist.

### BRIEF DESCRIPTION OF THE DRAWINGS

Example embodiments will be more clearly understood from the following detailed description taken in conjunction with the accompanying drawings. FIGS. 1-12 represent non-limiting, example embodiments as described herein.

FIGS. 1 to 8 are cross-sectional views illustrating a method of forming a protection layer on a photoresist pattern and a method of forming a fine pattern using the same according to example embodiments; and

FIGS. 9 to 12 are cross-sectional views illustrating a method of forming a protection layer on a photoresist pattern and a method of forming a fine pattern using the same according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully hereinafter with reference to the accompanying drawings, in which example embodiments are shown. Example embodiments may, however, be embodied in different forms and should not be construed as limited to the embodiments set forth herein. Rather, these embodiments are provided so that this disclosure will be thorough and complete, and will fully convey the scope of the example embodiments to those skilled in the art. In the drawings, the thickness of layers and regions may be exaggerated for clarity. Like reference numerals designate like elements throughout the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

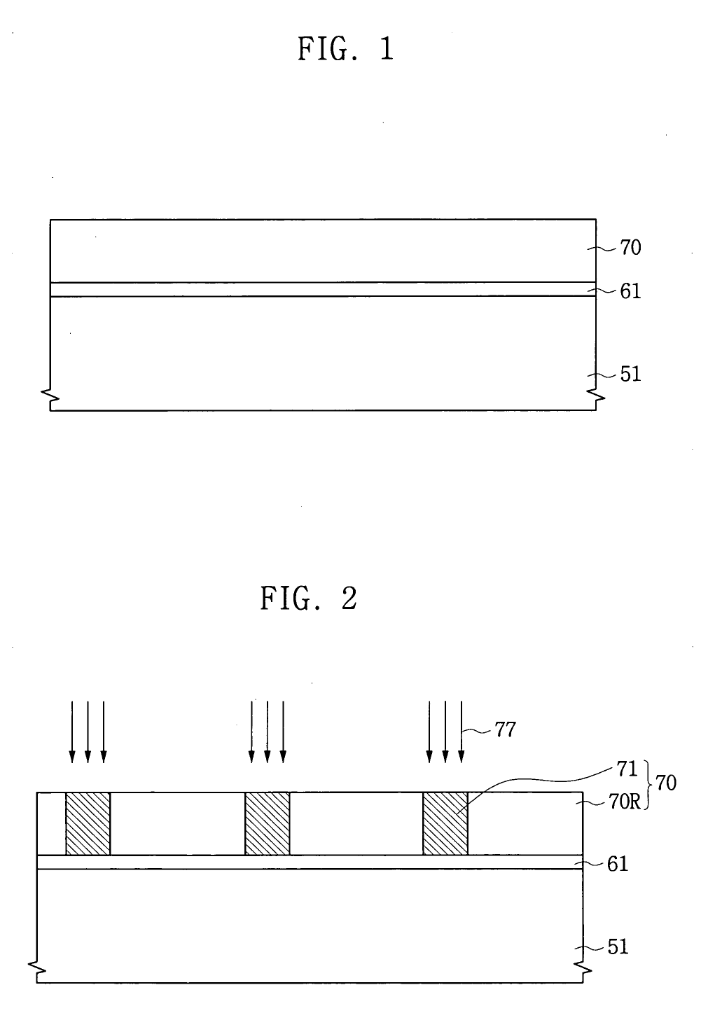

FIGS. 1 to 8 are cross-sectional views illustrating a method of forming a protection layer on a photoresist pattern and a method of forming a fine pattern using the same according to example embodiments. Referring to FIG. 1, an anti-reflective layer 61 and a photoresist layer 70 may be sequentially formed on a substrate 51. The substrate 51 may be a semiconductor substrate, e.g., a silicon wafer or a silicon on insulator (SOI) wafer. While an isolation layer, transistors and/or an interlayer dielectric layer may be additionally formed in the substrate 51, descriptions thereof will be omitted for clarity.

The anti-reflective layer 61 may be formed of an organic anti-reflective layer or an inorganic anti-reflective layer. The photoresist layer 70 may be formed by applying a negative photoresist on the anti-reflective layer 61. However, the anti-reflective layer 61 may be omitted. The substrate 51 having the photoresist layer 70 may be soft-baked at a temperature of about 50° C. to about 150° C. In example embodiments, organic solvents contained in the photoresist layer 70 may be evaporated.

Referring to FIG. 2, first exposure regions 71 may be formed on the photoresist layer 70 by a first exposure process 77. A reduction exposure technique that uses a chrome mask or a phase shift mask may be employed in the first exposure process 77. As a result, the photoresist layer 70 may be defined to the first exposure regions 71 and non-exposure regions 70R. The first exposure regions 71 may be formed in a bar type, a circular type and/or a combination thereof when viewed from a top view. The photoresist layer 70 may be formed to a thickness corresponding to the depth of focus (DOF) of the first exposure process 77.

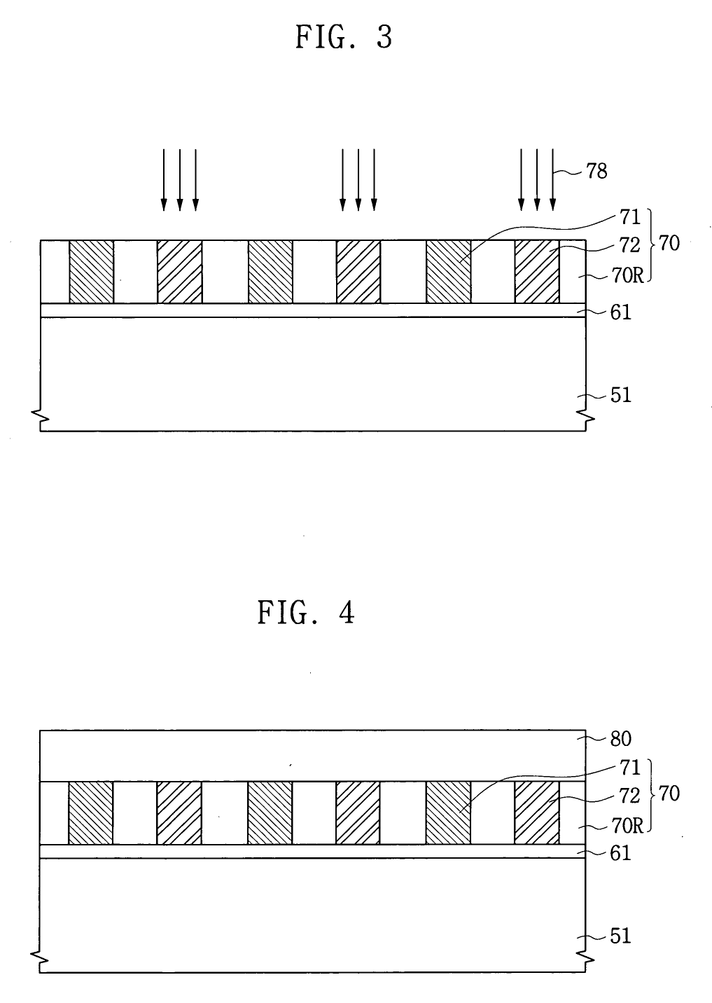

Referring to FIG. 3, second exposure regions 72 may be formed between the first exposure regions 71 by a second exposure process 78. The second exposure process 78 may employ a reduction exposure technique that uses a chrome mask or a phase shift mask. As a result, the non-exposure regions 70R may remain between the first exposure regions 71 and the second exposure regions 72. For example, the photoresist layer 70 may be defined to the first exposure regions 71, the second exposure regions 72 and the non-exposure regions 70R. The second exposure regions 72 may be formed in a bar type, a circular type and/or a combination thereof when viewed from a top view. The photoresist layer 70 may be formed to a thickness corresponding to the depth of focus (DOF) of the first exposure process 77 and the second exposure process 78.

Referring to FIG. 4, a reactive material layer 80 may be formed on the photoresist layer 70 having the exposure regions 71 and 72. The reactive material layer 80 may be formed to cover the substrate 51 and to be in contact with upper surfaces of the exposure regions 71 and 72. For example, the reactive material layer 80 may be formed to cover the exposure regions 71 and 72 and the non-exposure regions 70R.

The reactive material layer 80 may be formed of a material layer that may be dissolved in an organic solvent or water. The reactive material layer 80 may be formed of at least one selected from an acrylate group represented by Formula 1, a poly hydroxy styren (PHS) group represented by Formula 2, and a poly vinyl alcohol (PVA) group represented by Formula 3.

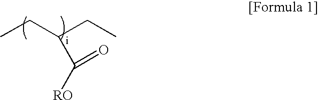

wherein R represents one selected from an electron donating group consisting of an alkyl group and H, and i represents an integer of 1 to 5000.

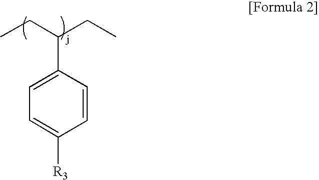

wherein R₃ represents one selected from an electron donating group consisting of an alkyl group and H or one selected from a blocking group consisting of tertiary-butyloxycarbonyl (t-Boc) and acetal, and j represents an integer of 1 to 5000.

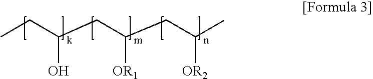

wherein R₁ and R₂, respectively, represent one selected from the group consisting of acetyl, acetal, an alkyl group and H, and k, m and n, respectively, represent an integer of 1 to 100.

For example, in Formula 3, R₁ may be acetyl, and R₂ may be acetal.

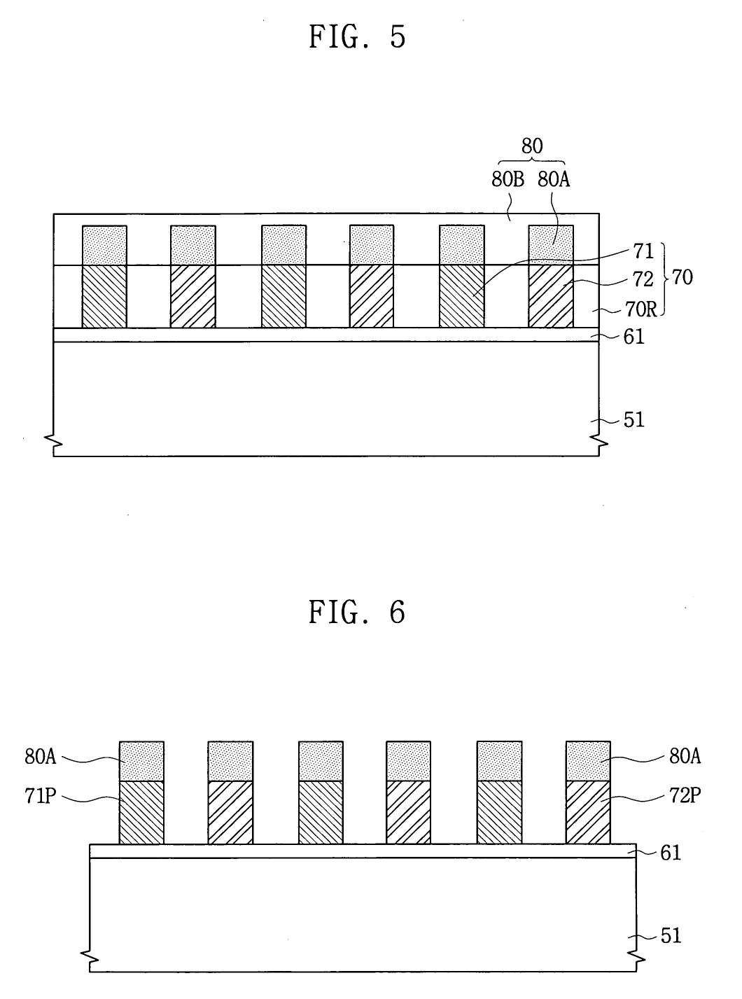

Referring to FIG. 5, the reactive material layer 80 may be reacted by a chemical attachment process to form a protection layer 80A on the exposure regions 71 and 72. For example, the chemical attachment process may include heating the photoresist layer 70 and the reactive material layer 80. Heating the photoresist layer 70 and the reactive material layer 80 may be performed at a temperature of about 90° C. to about 150° C. for about 60 seconds to about 90 seconds. Hydrogen ions (H+) may be generated from the exposure regions 71 and 72 to be diffused into the reactive material layer 80.

The reactive material layer 80, to which the hydrogen ions H+ may be diffused, may be crystallized to form the protection layer 80A. A non-reactive material layer 80B may remain on the non-exposure regions 70R. Also, the non-reactive material layer 80B may remain on the protection layer 80A. As a result, the reactive material layer 80 may be defined to the protection layer 80A and the non-reactive material layer 80B. The protection layer 80A may be formed to cover the exposure regions 71 and 72.

Referring to FIG. 6, the non-reactive material layer 80B and the non-exposure regions 70R may be removed by a development process. The exposure regions 71 and 72 that remain on the substrate 51 may constitute photoresist patterns 71P and 72P. The protection layer 80A may remain on the photoresist patterns 71P and 72P.

The development process may include a process that uses an organic solvent or water and/or alternately uses the same. The reactive material layer 80 may be a material layer that has characteristics dissolved in an organic solvent or water. The protection layer 80A may be not dissolved in the organic solvent or water because it may be combined with the hydrogen ions (H+) to thereby be crystallized. As a result, the non-reactive material layer 80B may be completely removed. In addition, when the photoresist layer 70 may be the negative photoresist, the non-exposure regions 70R may be removed by the organic solvent.

Accordingly, the anti-reflective layer 61 may be exposed between the photoresist patterns 71P and 72P. When the anti-reflective layer 61 is omitted, the substrate 51 may be exposed between the photoresist patterns 71P and 72P. The protection layer 80A may be formed to cover upper surfaces of the photoresist patterns 71P and 72P. Furthermore, sidewalls of the photoresist patterns 71P and 72P may be exposed. The protection layer 80A and the photoresist patterns 71P and 72P may be cured by a hard bake process. The hard bake process may be performed at a temperature of about 120° C. to about 250° C.

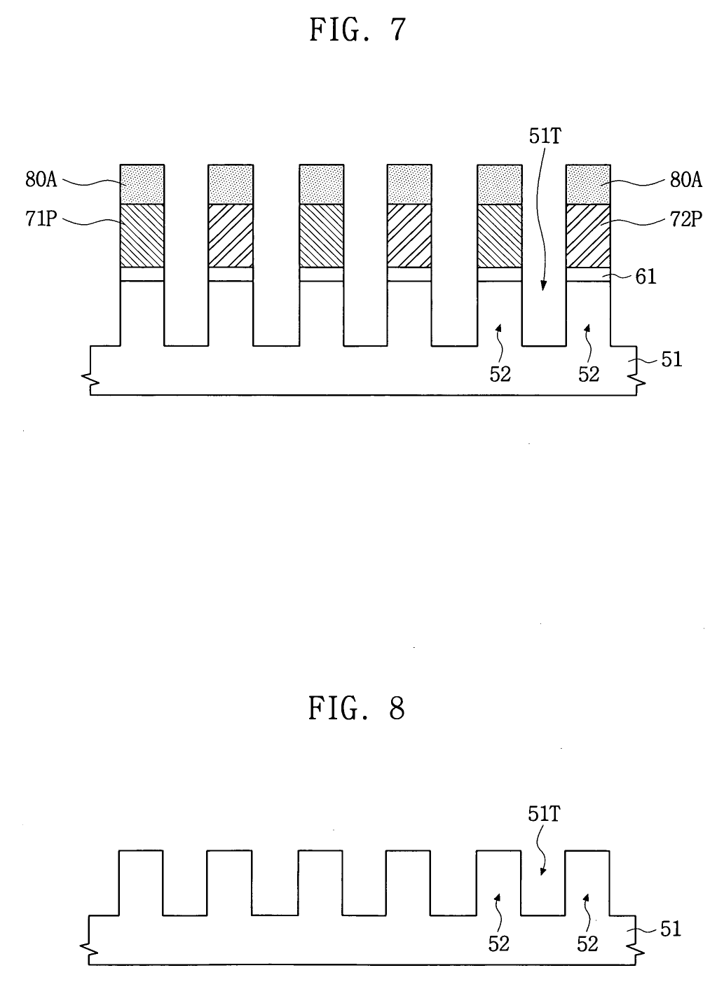

Referring to FIG. 7, the anti-reflective layer 61 and the substrate 51 may be etched using the protection layer 80A and the photoresist patterns 71P and 72P as etching masks to form trenches 51T that define active regions 52. Etching the substrate 51 may be performed by an anisotropic etching process, an isotropic etching process or a combination thereof. During the anisotropic etching process, the protection layer 80A and the photoresist patterns 71P and 72P may be etched at a predetermined or given ratio.

Referring to FIG. 8, the protection layer 80A, the photoresist patterns 71P and 72P and the anti-reflective layer 61 may be removed to expose the active regions 52. As described above, according to example embodiments, the first exposure regions 71 may be formed by the first exposure process 77, and the second exposure regions 72 may be formed by the second exposure process 78. The resolution limit of an exposure apparatus may be determined depending on the wavelength of a light source to be used. An exposure apparatus that requires higher resolution may use a light source having a shorter wavelength. The exposure apparatus that uses the light source having a shorter wavelength may exhibit a short DOF. Accordingly, the exposure apparatus that uses the light source having a shorter wavelength may require a photoresist layer having a smaller thickness.

Exposure apparatuses used for the first and second exposure processes 77 and 78 may obtain the sufficient resolution from a light source having a relatively long wavelength compared to an exposure apparatus for simultaneously exposing the exposure regions 71 and 72. Compared with when the exposure regions 71 and 72 are simultaneously exposed, the photoresist patterns 71P and 72P may be thicker. Further, the protection layer 80A may be self-aligned on the photoresist patterns 71P and 72P.

The protection layer 80A may act to support the photoresist patterns 71P and 72P while the substrate 51 may be etched. While the substrate 51 may be etched, the protection layer 80A and the photoresist patterns 71P and 72P may be etched at a predetermined or given ratio. However, the protection layer 80A and the photoresist patterns 71P and 72P may sufficiently act as etching masks to form the trenches 51T.

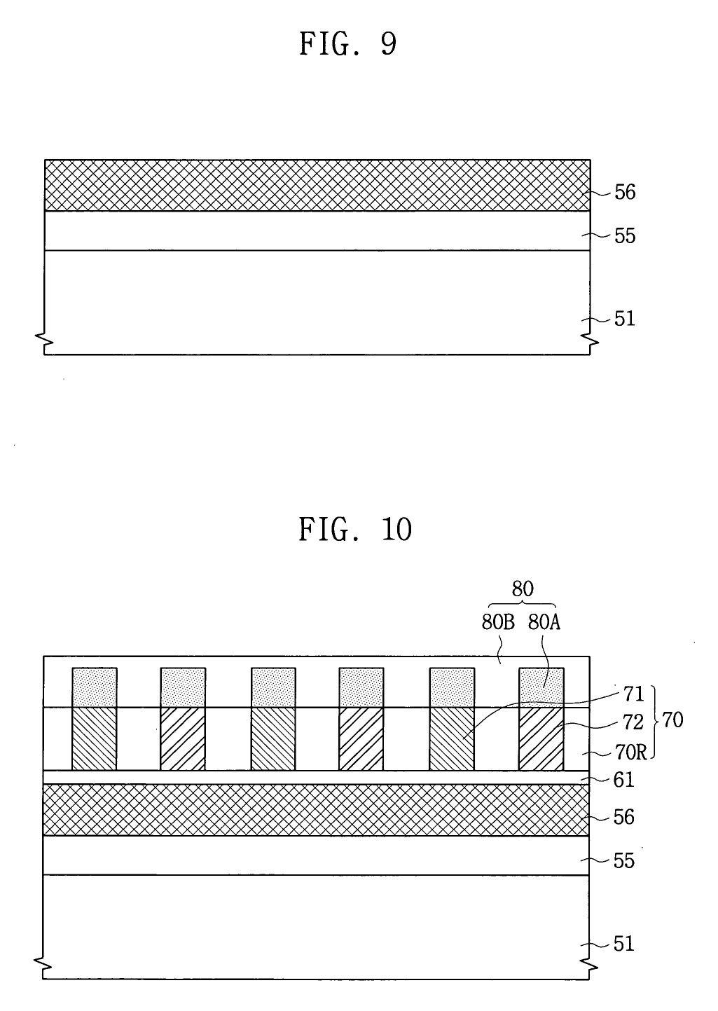

FIGS. 9 to 12 are cross-sectional views illustrating a method of forming a protection layer on a photoresist pattern and a method of forming a fine pattern using the same according to example embodiments. Referring to FIG. 9, a first thin film 55 and a second thin film 56 may be sequentially stacked on a substrate 51. The substrate 51 may be a semiconductor substrate, e.g., a silicon wafer or a silicon on insulator (SOI) wafer. While an isolation layer, transistors and/or an interlayer dielectric layer are additionally formed in the substrate 51, descriptions thereof will be omitted for clarity. Only differences from other example embodiments will be described below.

The first thin film 55 may be formed of a dielectric layer, a conductive layer or a combination thereof. The second thin film 56 may be formed of a different material layer from the first thin film 55. The second thin film 56 may be formed of a dielectric layer, a conductive layer or a combination thereof. Other example embodiments, in which the first thin film 55 may be formed of an interlayer dielectric layer and the second thin film 56 may be formed of a conductive layer, will be described below.

Referring to FIG. 10, an anti-reflective layer 61 and a photoresist layer 70 may be sequentially formed on the second thin film 56. The photoresist layer 70 may be formed by applying a negative photoresist on the anti-reflective layer 61. The substrate 51 having the photoresist layer 70 may be soft-baked at a temperature of about 50° C. to about 150° C.

First exposure regions 71 may be formed on the photoresist layer 70 by a first exposure process 77 (see FIG. 2). Second exposure regions 72 may be formed between the first exposure regions 71 by a second exposure process 78 (see FIG. 3). As a result, the photoresist layer 70 may be defined as the first exposure regions 71, the second exposure regions 72 and non-exposure regions 70R. The photoresist layer 70 may be formed to a thickness corresponding to the DOF of the first exposure process 77 and the second exposure process 78.

A reactive material layer 80 may be formed on the photoresist layer 70 having the exposure regions 71 and 72. The reactive material layer 80 may be formed to cover the substrate 51 and to be in contact with upper surfaces of the exposure regions 71 and 72. The reactive material layer 80 may be formed to cover the exposure regions 71 and 72 and the non-exposure regions 70R.

The reactive material layer 80 may be formed of a material layer that may be dissolved in an organic solvent or water. The reactive material layer 80 may be formed of at least one selected from an acrylate group represented by Formula 1, a poly hydroxy styren (PHS) group represented by Formula 2, and a poly vinyl alcohol (PVA) group represented by Formula 3. The reactive material layer 80 may be reacted by a chemical attachment process to form a protection layer 80A on the exposure regions 71 and 72.

For example, the chemical attachment process may include heating the photoresist layer 70 and the reactive material layer 80. Heating the photoresist layer 70 and the reactive material layer 80 may be performed at a temperature of about 90° C. to about 150° C. for about 60 seconds to about 90 seconds. Hydrogen ions (H+) may be generated from the exposure regions 71 and 72 to be diffused into the reactive material layer 80.

The reactive material layer 80, to which the hydrogen ions H+ may be diffused, may be crystallized to form the protection layer 80A. A non-reactive material layer 80B may remain on the non-exposure regions 70R. Also, the non-reactive material layer 80B may remain on the protection layer 80A. As a result, the reactive material layer 80 may be defined to the protection layer 80A and the non-reactive material layer 80B. The protection layer 80A may be formed to cover the exposure regions 71 and 72.

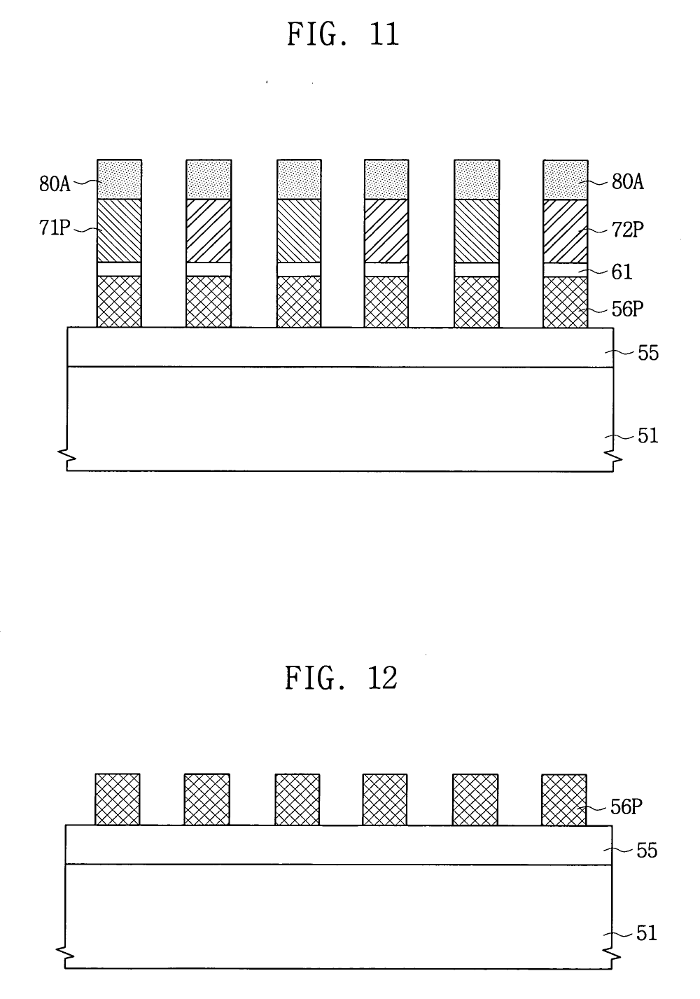

Referring to FIG. 11, the non-reactive material layer 80B and the non-exposure regions 70R may be removed by a development process. The exposure regions 71 and 72 that remain on the substrate 51 may constitute photoresist patterns 71P and 72P. The protection layer 80A may remain on the photoresist patterns 71P and 72P.

The development process may include a process that uses an organic solvent or water, and/or alternately uses the same. The reactive material layer 80B may be a material layer that has characteristics dissolved in an organic solvent or water. The protection layer 80A may not be dissolved in the organic solvent or water because it may be combined with the hydrogen ions (H+) to thereby be crystallized. As a result, the non-reactive material layer 80B may be completely removed. In addition, when the photoresist layer 70 is the negative photoresist, the non-exposure regions 70R may be removed by the organic solvent.

Accordingly, the anti-reflective layer 61 may be exposed between the photoresist patterns 71P and 72P. When the anti-reflective layer 61 is omitted, the second thin film 56 may be exposed between the photoresist patterns 71P and 72P. The protection layer 80A may cover upper surfaces of the photoresist patterns 71P and 72P. Furthermore, sidewalls of the photoresist patterns 71P and 72P may be exposed. The protection layer 80A and the photoresist patterns 71P and 72P may be cured by a hard bake process. The hard bake process may be performed at a temperature of about 120° C. to about 250° C.

The exposed anti-reflective layer 61 may be removed to expose the second thin film 56 between the photoresist patterns 71P and 72P. The second thin film 56 may be etched using the protection layer 80A and the photoresist patterns 71P and 72P as etching masks to form conductive patterns 56P. Etching the second thin film 56 may be performed by an anisotropic etching process, an isotropic etching process or a combination thereof. While the anisotropic etching process may be performed, the protection layer 80A and the photoresist patterns 71P and 72P may be etched at a predetermined or given ratio as well.

Referring to FIG. 12, the protection layer 80A, the photoresist patterns 71P and 72P and the anti-reflective layer 61 may be removed to expose the conductive patterns 56P. As described above, according to example embodiments, the first exposure regions 71 may be formed by the first exposure process 77, and the second exposure regions 72 may be formed by the second exposure process 78. Exposure apparatuses used for the first and second exposure processes 77 and 78 may obtain the sufficient resolution from a light source having a relatively long wavelength compared to an exposure apparatus for simultaneously exposing the exposure regions 71 and 72. Compared with when the exposure regions 71 and 72 may be simultaneously exposed, the photoresist patterns 71P and 72P may be thicker.

Further, the protection layer 80A may be self-aligned on the photoresist patterns 71P and 72P. The protection layer 80A may act to support the photoresist patterns 71P and 72P while the second thin film 56 may be etched. While the second thin film 56 is etched, the protection layer 80A and the photoresist patterns 71P and 72P may be etched at a predetermined or given ratio as well. However, the protection layer 80A and the photoresist patterns 71P and 72P may sufficiently act as etching masks to form the conductive patterns 56P.

As described above, according to example embodiments, exposure regions and non-exposure regions may be defined in a photoresist layer that covers a substrate by a twice-performed exposure process. A reactive material layer may be formed on the photoresist layer. A protection layer may be formed on the exposure regions by a chemical attachment process. The non-exposure regions and the reactive material layer that remains after the reaction may be removed by a development process to form photoresist patterns. The protection layer may remain on the photoresist patterns. The substrate may be etched using the protection layer and the photoresist patterns as etching masks. The protection layer may act to support the photoresist patterns while the substrate may be etched. Accordingly, the protection layer and the photoresist patterns may sufficiently act as etching masks for forming fine patterns.

Example embodiments have been disclosed herein and, although specific terms may be employed, they may be used and may be to be interpreted in a generic and descriptive sense only and not for purpose of limitation. Accordingly, it will be understood by those of ordinary skill in the art that various changes in form and details may be made without departing from the spirit and scope of the following claims.

What is claimed is:

1. A method of forming a protection layer on a photoresist pattern, comprising:
forming a photoresist layer on a substrate;
defining exposure regions and non-exposure regions in the photoresist layer using an exposure process;
forming a reactive material layer on the photoresist layer having the exposure regions;
forming a protection layer on the exposure regions by reacting the reactive material layer using a chemical attachment process; and
forming photoresist patterns by removing the non-exposure regions and the reactive material layer that remains after the reaction using a development process, wherein the protection layer remains on the photoresist patterns.

2. The method of claim 1, wherein the photoresist layer is made of a negative photoresist.

3. The method of claim 1, before forming the photoresist layer, further comprising:
forming an anti-reflective layer on the substrate.

4. The method of claim 1, wherein the reactive material layer is formed to cover the exposure regions and the non-exposure regions.

5. The method of claim 1, wherein defining the exposure regions and the non-exposure regions comprises:
forming first exposure regions in the photoresist layer using a first exposure process; and
forming second exposure regions between the first exposure regions using a second exposure process.

6. The method of claim 1, wherein the chemical attachment process comprises heating the photoresist layer and the reactive material layer to diffuse hydrogen ions (H+) generated from the exposure regions into the reactive material layer.

7. The method of claim 6, wherein heating the photoresist layer and the reactive material layer is performed at a temperature of about 90° C. to about 150° C.

8. The method of claim 1, wherein the protection layer is formed to cover the exposure regions, and the reactive material layer that does not react remains on the non-exposure regions.

9. The method of claim 1, wherein sidewalls of the photoresist patterns are exposed.

10. The method of claim 1, wherein the reactive material layer is formed of at least one selected from an acrylate group represented by Formula 1, a poly hydroxy styren (PHS) group represented by Formula 2, and a poly vinyl alcohol (PVA) group represented by Formula 3: 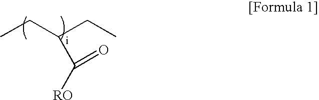
wherein R represents one selected from an electron donating group consisting of an alkyl group and H, and i represents an integer of 1 to 5000; 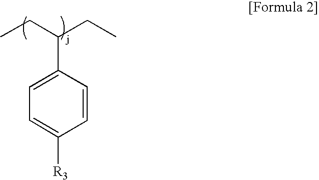
wherein R₃ represents one selected from an electron donating group consisting of an alkyl group and H or one selected from a blocking group consisting of tertiary-butyloxycarbonyl (t-Boc) and acetal, and j represents an integer of 1 to 5000; and 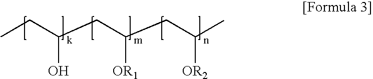
wherein R₁ and R₂, respectively, represent one selected from the group consisting of acetyl, acetal, an alkyl group and H, and k, m and n, respectively, represent an integer of 1 to 100.

11. A method of forming a fine pattern, comprising:
providing the substrate;
forming the protection layer according to claim 1; and
etching the substrate using the protection layer and the photoresist patterns as etching masks.

12. The method of claim 11, wherein providing the substrate comprises:
preparing a semiconductor substrate; and
forming one thin film selected from the group consisting of a conductive layer, a dielectric layer, and a combination thereof on the semiconductor substrate.

13. The method of claim 11, wherein the photoresist layer is made of a negative photoresist.

14. The method of claim 11, before forming the photoresist layer, further comprising:
forming an anti-reflective layer on the substrate.

15. The method of claim 11, wherein the reactive material layer is formed to cover the exposure and non-exposure regions.

16. The method of claim 11, wherein defining the exposure regions and the non-exposure regions comprises:
forming first exposure regions in the photoresist layer using a first exposure process; and
forming second exposure regions between the first exposure regions using a second exposure process.

17. The method of claim 11, wherein the chemical attachment process comprises heating the photoresist layer and the reactive material layer to diffuse hydrogen ions (H+) generated from the exposure regions into the reactive material layer.

18. The method of claim 11, wherein the protection layer is formed to cover the exposure regions, and the reactive material layer that does not react remains on the non-exposure regions.

19. The method of claim 11, wherein sidewalls of the photoresist patterns are exposed.

20. The method of claim 11, wherein the reactive material layer is formed of at least one selected from an acrylate group represented by Formula 1, a poly hydroxy styren (PHS) group represented by Formula 2, and a poly vinyl alcohol (PVA) group represented by the following Formula 3: 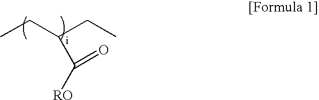
wherein R represents one selected from an electron donating group consisting of an alkyl group and H, and i represents an integer of 1 to 5000; 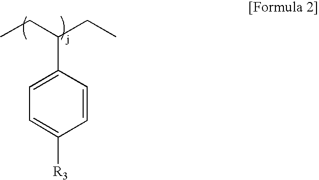
wherein R₃ represents one selected from an electron donating group consisting of an alkyl group and H or one selected from a blocking group consisting of tertiary-butyloxycarbonyl (t-Boc) and acetal, and j represents an integer of 1 to 5000; and 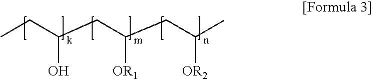
wherein R₁ and R₂, respectively, represent one selected from the group consisting of acetyl, acetal, an alkyl group and H, and k, m and n, respectively, represent an integer of 1 to 100.
